(19) United States
(12) Patent Application Publication
(10) Pub. No.: US 2009/0146725 A1
(43) Pub. Date: Jun. 11, 2009

(54) TEMPERATURE SENSOR CIRCUIT

(75) Inventor: Katsuji KIMURA, Nakahara-ku (JP)

Correspondence Address: SUGHRUE MION, PLLC, 2100 PENNSYLVANIA AVENUE, N.W., SUITE 800, WASHINGTON, DC, 20037, US

(73) Assignee: NEC Electronics Corporation, Nakahara-ku (JP)

(21) Appl. No.: 12/330,297

(22) Filed: Dec. 8, 2008

(30) Foreign Application Priority Data
Dec. 11, 2007 (JP) 2007-319764

(51) Int. Cl. H01L 35/00

(52) U.S. Cl. 327/512

(57) ABSTRACT

Disclosed is a temperature sensor circuit including a bipolar differential pair driven by a constant current and having an emitter area ratio of 1:N (N>1) and two MOS transistors having the transistor size ratio of K:1 (K>1) connected as an active load to the bipolar differential pair. A reference voltage is applied to one of the transistors of the bipolar differential pair. The other transistor has a base and a collector connected together. A desired voltage is output between the bases of the two transistors of the bipolar differential pair. A plural number of the temperature sensor circuits may be connected in cascade (FIG. 3).

### REFERENCE TO RELATED APPLICATION

This application is based upon and claims the benefit of the priority of Japanese patent application No. 2007-319764, filed on Dec. 11, 2007, the disclosure of which is incorporated herein in its entirety by reference thereto.

### TECHNICAL FIELD

This invention relates to a temperature sensor circuit. More particularly, it relates to a temperature sensor circuit which may be operated at a low voltage, may exhibit good temperature linearity, and which may be formed with advantage on a semiconductor integrated circuit.

### BACKGROUND

Among known temperature sensor circuits of this type, there is such a circuit that makes use of a forward voltage of a diode, as shown in FIG. 1. The forward voltage of the diode has a negative temperature characteristic, in which the temperature coefficient is −2.2 mV/° C. or −1.9 mV/° C.

However, the diode forward voltage suffers marked temperature non-linearity and, when it is used for a temperature sensor, an error is necessarily increased. The diode forward voltage at a temperature Tr is represented by the following equation (1):

$${V}_{D} \approx {V}_{g 0} - \frac{T}{{T}_{r}} [ {V}_{g 0} - {V}_{D} ( {T}_{r} ) ] - ( η - χ ) {V}_{T} ln ( \frac{T}{{T}_{r}} ) \qquad ( 1 )$$

where V_{T} is a thermal voltage, V_{go} is a diode voltage at 0K,VD Tr is a diode forward voltage at a temperature Tr, η is a process dependent coefficient that assumes a value between 3.6 and 4.0 and χ is a temperature dependent coefficient represented by I_{D}=DT^{χ} and which is equal to unity for the PTAT (proportional-to-absolute-temperature) current.

Also, it may be desired to amplify the so obtained diode forward voltage of the diode to a more or less large signal level for ease in signal handling. Even in such case, the diode forward voltage is rather large and is on the order of 0.6V, such that, if this voltage per se should be amplified, the power supply voltage exceeds a preset value, such as 3V, to render it difficult to implement the circuit.

### [Patent Document 1]

JP Patent No. 2666843

### SUMMARY OF THE DISCLOSURE

The following analysis is made from the side of the present invention.

With the above-described temperature sensor circuit, in which the diode forward voltage is exploited, it becomes difficult to improve the accuracy because of temperature non-linearity. Or, if it is desired to amplify the diode forward voltage to a more or less large signal level, the diode forward voltage is rather large and is on the order of 0.6V. If this voltage is amplified, the power supply voltage increases to a higher value to render it impossible to implement the circuit. That is, the above-described temperature sensor circuit suffers the following problems:

The first problem is that the accuracy in sensing temperature cannot be improved because of temperature non-linearity in the diode forward voltage.

The second problem is that the terminal voltage of the diode cannot be amplified because the diode forward voltage is as large as approximately 0.6V so that limitation is imposed from the power supply voltage.

Accordingly, it is an object of the present invention to provide a temperature sensor circuit which may be operated at a voltage from and inclusive of a low voltage, may exhibit good temperature linearity and which may be formed with advantage on a semiconductor integrated circuit.

According to the present invention, there is provided a temperature sensor circuit comprising: a bipolar differential pair including first and second bipolar transistors driven by a constant current and first and second transistors connected to the bipolar differential pair as an active load thereof. The first and second bipolar transistors have an emitter area ratio of 1:N (where N>1) and the first and second transistors have a transistor size ratio of K:1 (where K>1). The first bipolar transistor receives a preset reference voltage at a base thereof, the second bipolar transistor having a base and a collector coupled together. An output voltage is produced between the bases of the first and second transistors.

According to the present invention, a plurality of the above temperature sensor circuits may sequentially cascade-connected.

In one embodiment of the present invention, the temperature sensor circuit further comprises an amplifier circuit for amplifying the output voltage of the temperature sensor circuit. In the present invention, the amplifier circuit includes a differential amplifier comprising: a bipolar differential pair including third and fourth bipolar transistors driven by a constant current and having an emitter area ratio of N:1 (where N>1); and third and fourth transistors connected to the bipolar differential pair as an active load thereof, the third and fourth transistors having a transistor size ratio of K:1 (where K>1).

In one embodiment of the present invention, the first and second transistors constitute a current mirror. The first transistor having a larger transistor size being connected to the first bipolar transistor of the bipolar differential pair having a smaller emitter area and the second transistor having a smaller transistor size being connected to the second bipolar transistor having a larger emitter area.

In one embodiment of the present invention, the third and fourth transistors constitute a current mirror. The third transistor having a smaller transistor size being connected to the third bipolar transistor having a larger emitter area and the fourth transistor having a larger transistor size being connected to the fourth bipolar transistor of the bipolar differential pair having a smaller emitter area.

In one embodiment of the present invention, in a first stage temperature sensor circuit out of a plurality of the temperature sensor circuits connected in cascade, the first bipolar transistor of the bipolar differential pair receives the preset reference voltage at a base thereof. In each of the second and following stage temperature sensor circuits, the first bipolar transistor of the bipolar differential pair receives an output voltage of the temperature sensor circuit of each preceding stage at a base thereof. In each stage temperature sensor circuit preceding the last stage temperature sensor circuit, an output voltage from a connection node of a base and a collector of the second bipolar transistor of the bipolar differential pair is supplied to each next stage temperature sensor circuit. In the last stage temperature sensor circuit, an output voltage from a connection node of a base and a collector of the second bipolar transistor of the bipolar differential pair is to be an output voltage of the plural stages of the temperature sensor circuits connected in cascade.

According to the present invention, temperature linearity is made excellent because the thermal voltage is exploited.

According to the present invention, a sensing signal may be amplified with ease because a desired voltage may be obtained as a differential voltage.

According to the present invention, a lower voltage may be implemented because the desired voltage may be obtained as a differential voltage on a differential circuit.

Still other features and advantages of the present invention will become readily apparent to those skilled in this art from the following detailed description in conjunction with the accompanying drawings wherein only the preferred embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a schematic circuit diagram showing a configuration of a temperature sensor circuit formed by using a diode according to a conventional technique.

FIG. 2 is a schematic circuit diagram showing a circuit configuration of an exemplary embodiment of the present invention.

FIG. 3 is a schematic circuit diagram showing a circuit configuration of another exemplary embodiment of the present invention.

FIG. 4 is a schematic circuit diagram showing a circuit configuration of a further exemplary embodiment of the present invention.

### PREFERRED MODES OF THE INVENTION

Exemplary embodiments of the present invention are now described with reference to the drawings.

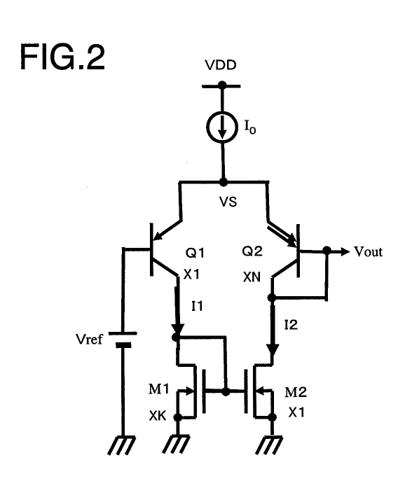

FIG. 2 depicts a circuit configuration of an exemplary embodiment of a temperature sensor circuit. This configuration corresponds to claim 1. Referring to FIG. 2, the circuit includes a bipolar differential pair transistors (pnp bipolar transistors) (Q1, Q2), having coupled emitters connected to one end of a constant current source I0, the other end of which is connected to a power supply VDD and N-channel MOS transistors (M1, M2) which are connected to the collectors of the differential pair transistors (Q1, Q2) to constitute a current mirror. A reference voltage (constant voltage) Vref is applied to the base of the bipolar transistor Q1. The collector and the base of the bipolar transistor Q2 are connected together and an output voltage Vout is produced at the connection node of the collector and base of the bipolar transistor Q2.

The bipolar transistors Q1 and Q2 are non-matched (unsymmetrical) differential pair having an emitter area ratio of 1:N (N>1), and are driven by the constant current I0. The MOS transistor M1 has a drain and a gate connected together and connected to a collector of the transistor Q1, while having a source connected to GND. The MOS transistor M2 has a drain connected to the collector of the transistor Q2, while having a gate connected to the gate of the MOS transistor M1 and having a source connected to GND.

To the differential pair, made up of the bipolar transistors Q1 and Q2, there is connected an active load made up of two transistors having a transistor size ratio equal to K:1 (K>1). The transistor size ratio may, for example, be the W/L ratio, where W is a gate width and L is a gate length. The currents flowing through the transistors Q1 and Q2 (collector currents) are set to a current ratio of K:1. A differential amplifier circuit including a bipolar differential pair including transistors (Q1, Q2) and current mirror transistors (Q3, Q4) that form an active load of the bipolar differential pair is disclosed in Patent Document 1, for instance. The coupled emitters of the transistors (Q1, Q2) are connected to a constant current source, with the emitter area ratio of the transistors being m:1. The transistors (Q3, Q4) form a current mirror that constitutes an active load of the bipolar transistor pair, with the emitter area ratio of the transistors being 1:n.

The input offset voltage generated in the non-matched differential pair made up of the bipolar transistors Q1 and Q2 is represented by

V_{OS}=V_{ref}−Vₒᵤₜ=V_{T} ln(KN) (2)

where V_{T} is a thermal voltage represented by

$${V}_{T} = \frac{kT}{q} \qquad ( 3 )$$

where k is the Boltzmann constant, q is the electron charge and T is an absolute temperature (Kelvin temperature).

The equation (2) is derived as follows: In FIG. 2, the collector currents I1 and I2 of the bipolar transistors Q1 and Q2 may be given by the following equations (4) and (5), respectively:

$$\begin{matrix}{I}_{1} = {I}_{S} exp ( \frac{{V}_{BE 1}}{{V}_{T}} ) & ( 4 ) \\ {I}_{2} = {NI}_{S} exp ( \frac{{V}_{BE 2}}{{V}_{T}} ) & ( 5 )\end{matrix}$$

where Is is a reverse-direction collector saturation current and V_{BE1} and V_{BE2} are base-to-emitter voltages of the transistors Q1 and Q2, respectively.

I₁ and I₂ are an input current and an output current of the current mirror circuit (M1, M2), respectively, and satisfy the following relationship (6):

I₁=KI₂ (6)

Referring to FIG. 2, the following equations (7) and (8) hold.

V_{BE1}=V_{ref} (7)

V_{BE2}=Vₒᵤₜ (8).

### Hence,

$$\begin{matrix}{V}_{OS} = {V}_{ref} - {V}_{out} \\ = {V}_{T} ln ( \frac{{I}_{1}}{{I}_{S}} ) - {V}_{T} ln ( \frac{{I}_{2}}{{NI}_{S}} ) \\ = {V}_{T} ln ( \frac{{NI}_{1}}{{I}_{2}} ) \\ = {V}_{T} ln ( NK )\end{matrix}$$

The thermal voltage V_{T} is a voltage proportional to absolute temperature (V_{PTAT}). That is, the temperature linearity of the voltage obtained (V_{OS} of the equation (2)) is perfect.

If, for example, N=12 and K=12, ln(KN)=4.9698133(≈5)

For 27° C. (300.15K), the thermal voltage V_{T} is found to be 25.85562 mV.

Thus, if N=12 and K=12, an input offset voltage at 27° C. (300.15K) is 128.4976 mV, with the temperature coefficient being 0.4281113 mV/° C.

The absolute value of this temperature coefficient is about one-fifth of the temperature coefficient of a diode of −2.2 mV/° C.

Or, with N=120 and K=120, the input offset voltage at 27° C. (300.15K) is 247.56713 mV, with the temperature coefficient being 0.824811376 mV/° C.

The absolute value of this temperature coefficient is about 1/2.67 of the temperature coefficient of a diode of −2.2 mV/° C.

The power supply voltage may be on the order of 1.5V because a voltage proportional to the temperature may be obtained as a differential voltage.

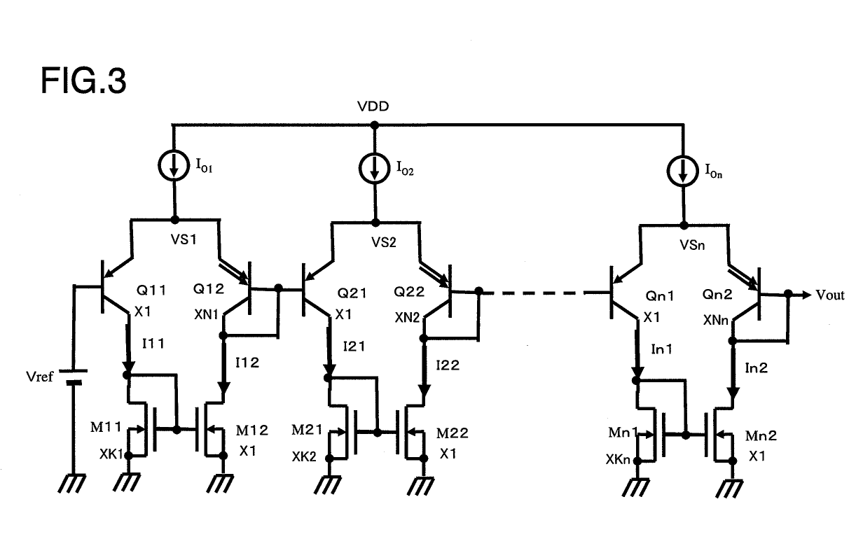

FIG. 3 shows an example of a temperature sensor circuit which corresponds to claim 2. Referring to FIG. 3, this circuit is formed by sequentially connecting a plurality of the temperature sensor circuits of FIG. 2 in cascade.

As described above, the temperature coefficient of the output voltage from the temperature sensor circuit varies with a log of the product of K and N or KN, that is, ln(KN), and hence becomes smaller than the temperature coefficient of a diode.

Hence, the cascade connection of a plurality of the temperature sensor circuits of FIG. 2 is desirable in that such connection improves the chip area efficiency.

For example, if two temperature sensor circuits with N=12 and K=12 are connected in cascade, the input offset voltage at 27° C. (300.15K) adds to itself and is thereby doubled to 256.9952 mV. The temperature coefficient is also doubled to 0.9642226 mV/° C.

The temperature coefficient, obtained in this case, is greater in magnitude than the temperature coefficient obtained with the temperature sensor circuit for N=120 and K=120 described above.

A temperature sensor circuit with N=12 and K=12 includes 13 unit bipolar transistors and 13 unit MOS transistors, whilst two temperature sensor circuits, each with N=12 and K=12, include 26 unit bipolar transistors and 26 unit MOS transistors.

On the other hand, a temperature sensor circuit with N=120 and K=120 includes 121 unit bipolar transistors and 121 unit MOS transistors.

That is, the temperature sensor circuit with N=120 and K=120 includes a number of unit bipolar transistors 9.3 times that of a temperature sensor circuit with N=12 and K=12 and a number of unit MOS transistors 9.3 times that of the temperature sensor circuit with N=12 and K=12.

The temperature sensor circuit with N=120 and K=120 includes a number of unit bipolar transistors equal to 4.65 times that of two temperature sensor circuits each with N=12 and K=12 and a number of unit MOS transistors equal to 4.65 times that of two temperature sensor circuits each with N=12 and K=12. Hence, the chip area efficiency in this case is quadrupled.

Five temperature sensor circuits each with N=12 and K=12 include 65 unit bipolar transistors and 65 unit MOS transistors.

If these five temperature sensor circuits are connected in cascade, five input offset voltages at 27° C. (300.15K) add together to a quintupled voltage of 642.488 mV. The temperature coefficient is also quintupled to 2.1405565 mV/° C. These values roughly correspond to the forward voltage of a diode and its temperature coefficient provided that their signs are inverted.

Only by way of reference, the case of N=1 and K=1 corresponds to a well-known case of a matched (symmetrical) differential pair having the function of a buffer amplifier with a unity gain. In such case, an input offset voltage of a differential pair varies in both plus and minus sides and has a normal distribution. An input offset voltage is assumed to be introduced unintentionally.

An input offset voltage in a matched bipolar differential pair is within ±1 mV. In case an input offset voltage of one hundred and few dozen mV of the input offset voltage is to be generated on the (+) or (−) side, with the use of a non-matched differential pair, as in the present invention, an unintentional input offset voltage, attributable to a factor or factors responsible for an input offset voltage innate to a matched differential pair, may be supposed to be 1% or less. The value of this order may be the to be negligible.

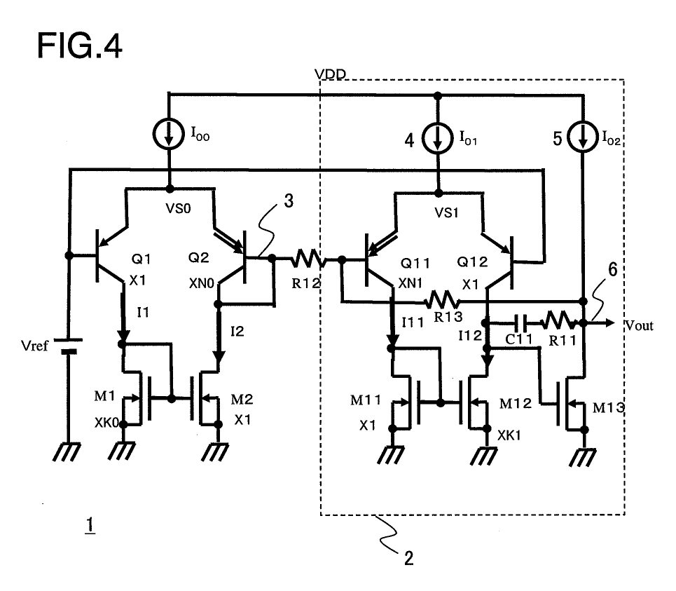

FIG. 4 shows a practical example of a temperature sensor circuit which correspond to claim 4. In this example, an output voltage of a temperature sensor circuit 1 or a plurality of temperature sensor circuits 1, connected in cascade, is amplified by a differential amplifier (inverting amplifier) 2.

The differential amplifier 2 includes a bipolar differential pair (pnp bipolar transistor differential pair) Q11 and Q12, N-channel MOS transistors M11 and M12, an N-channel MOS transistor M13 and a constant current source 5. The coupled emitters of the bipolar differential pair Q1 and Q12 are connected to one end of a constant current source 4, the other end of which is connected to a power supply VDD. The N-channel MOS transistors M11 and M12 are connected to the collectors of the bipolar differential pair Q11 and Q12 to constitute a current mirror. The N-channel MOS transistor M13 has its source connected to GND, while having its gate connected to a drain of the MOS transistor M12 and having its drain connected to an output terminal 6. The constant current source 5 is connected between the output terminal 6 and the power supply VDD. Between the output terminal 6 and the base of the bipolar transistor Q11 is connected a resistor (feedback resistor) R13. The base of the bipolar transistor Q11 is connected to an output terminal 3 of the temperature sensor circuit 1 via a resistor R12. Between the output terminal 6 of the differential amplifier 2 and the drain of the MOS transistor M12 are connected a resistor R11 and a capacity C11 (phase compensation capacitor) in series. The base of the bipolar transistor Q12 is connected to a reference voltage Vref. The emitter area ratio of the bipolar transistors Q11 and Q12 is set to N1:1, whilst the transistor size ratio (W/L ratio) of the N-channel MOS transistors M11 and M12, constituting the current mirror circuit, is set to 1:K1. The temperature sensor circuit 1 is configured as shown in FIG. 2, in which the reference voltage Vref is applied to the base of the bipolar transistor Q1, and a voltage is output at a collector-base connection node of the bipolar transistor Q2 (output terminal 3 of the temperature sensor circuit 1). This differential amplifier 2 is an inverting amplifier that amplifies the voltage with a gain equal to −R13/R12.

If a signal level obtained with the temperature sensor circuit 1 is low, the signal level is amplified by an amplifier, as is done customarily for such case. It should be noted that the amplifier is not constituted by a matched differential pair, but by a differential amplifier 2 made up of non-matched differential pair (Q11, Q12), as shown in FIG. 4. By so doing, an intentional input offset voltage may be added and, in this sort of the temperature sensor circuit, the voltage gain of the amplifier may correspondingly be reduced.

In the differential amplifier 2, constituted by the non-matched differential pair (Q11, Q12), simply an intentional input offset voltage, such as Vos of the equation (2), is added, so that, granting that an unintentional input offset voltage is added, its value is negligible.

It is supposed that n-stages of temperature sensor circuits are connected in cascade, and an output of the n'th stage temperature sensor circuit is amplified by a differential amplifier constituted by the non-matched differential pair (2 of FIG. 4) made up by the non-matched differential pair (Q11, Q12). In such case, an output voltage of the differential amplifier (2 of FIG. 4) is expressed as

V_{get}=(V_{OS1}+V_{OS2}+ . . . +V_{OSn})×G+V_{OSAMP} (9)

where V_{OS1,} . . . , V_{OSn} are output voltages of the respective temperature sensor circuits.

V_{O S A M P} is an input offset voltage produced in the differential amplifier 2 constituted by the non-matched differential pair (Q11, Q12).

It should be noted that, since the differential pair is constituted as an inverting amplifier, the voltage gain of the differential amplifier is given by

$$G = - \frac{R 13}{R 12} \qquad ( 10 )$$

If

V_{OS1}= . . . =V_{OSn}=−V_{OSAMP}=V_{OS} (11)

is set for simplicity, then we have

V_{get}=−V_{OS}×(nG+1) (12)

Here, it is adapted so that the sign (polarity) of the input offset voltage V_{O S A M P}, generated in the differential pair of the differential amplifier 2 (non-matched differential pair) (Q11, Q12), becomes different from that of the offsets (V_{O S 1}, . . . , V_{O S n}) produced in the temperature sensor circuits 1 situated at a preceding stage.

It is seen that cascaded connection of n stages of the temperature sensor circuits is equivalent to the voltage gain |G|. That is, by setting the number of the cascade connected temperature sensor circuits and the value of the voltage gain G in a desired manner, a desired voltage may be obtained to optimize the chip area. The voltage gain G of the amplifier may correspondingly be decreased by changing an amplifier to a differential amplifier constituted by a non-matched differential pair.

Since the voltage proportional to temperature may be obtained as a differential voltage, the power supply voltage on the order of 1.5V may be used.

The temperature sensor circuit of the present invention may be integrated on a semiconductor chip for use for temperature control of a wide variety of LSI chips.

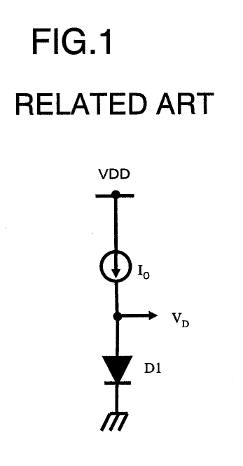

In the temperature sensor circuit or the differential amplifier, described above with reference to FIGS. 2 to 4, the bipolar differential pair (pnp transistors Q1 and Q2) or the current mirror (N-channel MOS transistors M1 and M2) operating as an active load for the bipolar differential pair may be of polarities opposite to those shown in FIGS. 1 and 2.

The disclosure of the aforementioned Patent Document 1 is incorporated by reference herein. The particular exemplary embodiments or examples may be modified or adjusted within the gamut of the entire disclosure of the present invention, inclusive of claims, based on the fundamental technical concept of the invention. Further, variegated combinations or selection of elements disclosed herein may be made within the framework of the claims. That is, the present invention may encompass various modifications or corrections that may occur to those skilled in the art in accordance with the within the gamut of the entire disclosure of the present invention, inclusive of claim and the technical concept of the present invention. It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A temperature sensor circuit comprising:
a bipolar differential pair including first and second bipolar transistors driven by a constant current, the first and second bipolar transistors having an emitter area ratio of 1:N (where N>1); and
first and second transistors connected to the bipolar differential pair as an active load thereof and having a transistor size ratio of K:1 (where K>1),
the first bipolar transistor receiving a preset reference voltage at a base thereof, the second bipolar transistor having a base and a collector coupled together, and an output voltage being produced between the bases of the first and second transistors.

2. The temperature sensor circuit comprising a plurality of the temperature sensor circuits connected in cascade, each of the temperature sensor circuits as set forth in claim 1.

3. The temperature sensor circuit according to claim 1, further comprising an amplifier circuit that amplifies the output voltage of the temperature sensor circuit.

4. The temperature sensor circuit according to claim 3, wherein the amplifier circuit includes a differential amplifier comprising:
a bipolar differential pair including third and fourth bipolar transistors driven by a constant current and having an emitter area ratio of N:1 (where N>1); and
third and fourth transistors connected to the bipolar differential pair as an active load thereof and having a transistor size ratio of K:1 (where K>1).

5. The temperature sensor circuit according to claim 1, wherein the first and second transistors constitute a current mirror, the first transistor having a larger transistor size being connected to the first bipolar transistor of the bipolar differential pair having a smaller emitter area, and the second transistor having a smaller transistor size being connected to the second bipolar transistor of the bipolar differential pair having a larger emitter area.

6. The temperature sensor circuit according to claim 4, wherein the third and fourth transistors constitute a current mirror, the third transistor having a smaller transistor size being connected to the third bipolar transistor of the bipolar differential pair having a larger emitter area, and the fourth transistor having a larger transistor size being connected to the fourth bipolar transistor of the bipolar differential pair having a smaller emitter area.

7. The temperature sensor circuit according to claim 4, wherein
in a first stage temperature sensor circuit out of a plurality of the temperature sensor circuits connected in cascade, the first bipolar transistor of the bipolar differential pair receives the preset reference voltage at a base thereof,
in each of the second and following stage temperature sensor circuits, the first bipolar transistor of the bipolar differential pair receives an output voltage of the temperature sensor circuit of each preceding stage at a base thereof,
in each stage temperature sensor circuit preceding the last stage temperature sensor circuit, an output voltage from a connection node of a base and a collector of the second bipolar transistor of the bipolar differential pair is supplied to each next stage temperature sensor circuit, and
in the last stage temperature sensor circuit, an output voltage from a connection node of a base and a collector of the second bipolar transistor of the bipolar differential pair is to be an output voltage of the plural stages of the temperature sensor circuits connected in cascade.

8. The temperature sensor circuit according to claim 7, further comprising an amplifier circuit that amplifies the output voltage of the last stage temperature sensor circuit out of the plural stages of temperature sensor circuits connected in cascade.

9. The temperature sensor circuit according to claim 8, wherein the amplifier circuit includes a differential amplifier comprising:
a bipolar differential pair driven by a constant current and having an emitter area ratio of 1:N (N>1); and
two transistors connected to the bipolar differential pair as an active load thereof, the two transistors having a transistor size ratio of K:1(K>1).

10. A temperature sensor circuit comprising:
a first current source having one end connected to a first power supply;
first and second bipolar transistors, having coupled emitters connected to the other end of the first current source, the first and second bipolar transistors having an emitter area ratio of 1:N0 (where N0>1); and
first and second MOS transistors having sources connected to a second power supply and having drains connected to collectors of the first and second bipolar transistors, respectively, the first and second MOS transistors having a transistor size ratio of K0:1 (where K0>1),
a base of the first bipolar transistor being connected to a terminal that is supplied with a preset reference voltage,
a collector and a base of the second bipolar transistor being connected together,
an output voltage being taken out at a connection node of the collector and the base of the second bipolar transistor, and
a drain and a gate of the first MOS transistor being connected together and connected to a gate of the second MOS transistor.

11. The temperature sensor circuit comprising:
a differential amplifier that amplifies an output voltage of the temperature sensor circuit as set forth in claim 10, the differential amplifier including:
a third current source having one end connected to the first power supply;
third and fourth bipolar transistors having coupled emitters connected to the other end of the second current source and having an emitter area ratio of N1:1 (where N1>1);
third and fourth MOS transistors having sources connected to the second power supply and having drains connected to collectors of the third and fourth bipolar transistors, respectively, and having a transistor size ratio of 1:K1 (where K1>1), a drain and a gate of the third MOS transistor being connected together and connected to the gate of the fourth MOS transistor;
an output transistor that is connected between an output terminal and the second power supply and that receives a voltage at a connection node of the collector of the fourth bipolar transistor and the drain of the fourth MOS transistor to drive the output terminal; and
a fourth current source connected between the first power supply and the output terminal,
a base of the third bipolar transistor being connected via a first resistor to an output of the temperature sensor circuit,
a base of the fourth bipolar transistor being supplied with the preset reference voltage supplied to the base of the first bipolar transistor of the temperature sensor circuit, and
a second resistor being connected between the output terminal and the base of the third bipolar transistor.

12. The temperature sensor circuit according to claim 1, wherein the first and second transistors are MOS transistors.

13. The temperature sensor circuit according to claim 4, wherein the third and fourth transistors are MOS transistors.
